(19) United States
(12) Patent Application Publication
(10) Pub. No.: US 2024/0321840 A1
(43) Pub. Date: Sep. 26, 2024

(54) THREE-DIMENSIONAL SEMICONDUCTOR PACKAGE

(71) Applicant: SAMSUNG ELECTRONICS CO.,LTD., Suwon-si (KR)

(72) Inventors: Jingfan YANG, Suzhou (CN); Peng Zhang, Suzhou (CN)

(73) Assignee: SAMSUNG ELECTRONICS CO.,LTD., Suwon-si (KR)

(21) Appl. No.: 18/596,240

(22) Filed: Mar. 5, 2024

(30) Foreign Application Priority Data
Mar. 24, 2023 (CN) 202310302211.X

(51) Int. Cl. H01L 25/10; H01L 23/00; H01L 23/31; H01L 23/48; H01L 23/538; H01L 25/065

(52) U.S. Cl. CPC H01L 25/105; H01L 23/3128; H01L 23/481; H01L 23/5383; H01L 23/5384; H01L 24/13; H01L 24/16; H01L 25/0657; H01L 2224/13; H01L 2224/16145; H01L 2224/16227; H01L 2225/06513; H01L 2225/06517

(57) ABSTRACT

A three-dimensional semiconductor package including: a package substrate having a first surface and a second surface opposite to the first surface; a first redistribution layer on the first surface of the package substrate, the first redistribution layer having a first surface and a second surface opposite to each other; a first chip on the first surface of the first redistribution layer, electrically connected to the first redistribution layer, and including first through silicon vias; first connection terminals electrically connected to one ends of the first through silicon vias; a second redistribution layer on the second surface of the package substrate, the second redistribution layer having a first surface and a second surface opposite to each other, the first surface of the second redistribution layer facing the second surface of the package substrate; and a second chip on the second surface of the second redistribution layer.

### CROSS-REFERENCE TO RELATED APPLICATION

This application claims priority to the Chinese Patent Application No. 202310302211.X filed on Mar. 24, 2023 in the China National Intellectual Property Administration, the disclosure of which is incorporated by reference herein in its entirety.

### BACKGROUND

### 1. Field

The present disclosure relates to a semiconductor package, and in particular, to a three-dimensional (3D) semiconductor package.

### 2. Description of Related Art

A semiconductor device becomes an important element in the electronic industry because of having advantages, such as a small size, multifunction, low cost, and the like. To achieve more integrated functions, multiple semiconductor devices may be packaged together to form a semiconductor package.

With the development of the electronic industry, a demand for a

semiconductor package with a higher density of integration and a faster transmission rate of electric signals is being increased. To this end, a scheme for increasing a density of electrical connections and a transmission rate of electric signals in a semiconductor package including a logic chip and a cache chip through a silicon (Si) substrate or a Si interposer, in which through silicon vias (TSVs) are formed, has been proposed. However, current Si substrates or Si interposers have issues of, for example, being relatively high in cost and relatively low in yield. Accordingly, there is a demand for seeking an alternative scheme to the Si substrates or the Si interposers.

### SUMMARY

One or more example embodiments provide a three-dimensional (3D) semiconductor package with an improved transmission rate of electric signals and a reduced package size.

One or more example embodiments provide a method of manufacturing a 3D semiconductor package with an improved transmission rate of electric signals and a reduced package size.

According to an aspect of an example embodiment, a three-dimensional semiconductor package includes: a package substrate having a first surface and a second surface opposite to the first surface; a first redistribution layer on the first surface of the package substrate, the first redistribution layer having a first surface and a second surface opposite to each other, the second surface of the first redistribution layer facing the surface of the package substrate; a first chip on the first surface of the first redistribution layer, electrically connected to the first redistribution layer, and comprising first through silicon vias; first connection terminals electrically connected to one ends of the first through silicon vias, the other ends of the first through vias being closer to the first redistribution layer; a second redistribution layer on the second surface of the package substrate, the second redistribution layer having a first surface and a second surface opposite to each other, the first surface of the second redistribution layer facing the second surface of the package substrate; and a second chip on the second surface of the second redistribution layer and electrically connected to the second redistribution layer, wherein the first redistribution layer and the second redistribution layer are interconnected through the package substrate, and wherein the first chip and the second chip are disposed within a periphery of the package substrate when viewed in a plan view.

According to an aspect of an example embodiment, a three-dimensional semiconductor package includes: a package substrate having a first surface and a second surface opposite to the first surface; a first redistribution layer on the first surface of the package substrate; a first chip on the first redistribution layer and electrically connected to the first redistribution layer, and comprising first through silicon vias; first connection terminals electrically connected to ends of the first through silicon vias; a second redistribution layer on the second surface of the package substrate; and a second chip on the second redistribution layer and electrically connected to the second redistribution layer, wherein the first chip and the second chip are disposed within a periphery of the package substrate when viewed in a plan view.

According to an aspect of an example embodiment, a three-dimensional semiconductor package includes: a package substrate having a first surface and a second surface opposite to the first surface; a first redistribution layer on the first surface of the package substrate; a plurality of first chips on the first redistribution layer and electrically connected to the first redistribution layer, and comprising first through silicon vias; first connection terminals electrically connected to ends of the first through silicon vias; a second redistribution layer on the second surface of the package substrate; a plurality of second chips on the second redistribution layer and electrically connected to the second redistribution layer; first connection members between the plurality of first chips and the first redistribution layer and electrically connecting the plurality of first chips to the first redistribution layer; and second connection members between the plurality of second chips and the second redistribution layer and electrically connecting the plurality of second chips to the second redistribution layer.

### BRIEF DESCRIPTION OF DRAWINGS

The above and other aspects and features will be more apparent from the following description of example embodiments, taken in conjunction with the accompanying drawings, in which:

FIG. 1A is a schematic cross-sectional view illustrating a three-dimensional (3D) semiconductor package according to an example embodiment.

FIG. 1B is a schematic top view illustrating a 3D semiconductor package according to an example embodiment.

FIG. 1C is a schematic bottom view illustrating a 3D semiconductor package according to an example embodiment.

FIGS. 2A to 2C are schematic cross-sectional views illustrating stages of a method of manufacturing a 3D semiconductor package according to an example embodiment.

FIGS. 3A and 3B are schematic layout diagrams illustrating a plurality of first chips according to an example embodiment.

FIG. 4 is a schematic layout diagram illustrating a plurality of second chips according to an example embodiment.

FIG. 5 is a schematic diagram illustrating a 3D semiconductor package when being mounted on an external circuit board, according to an example embodiment.

FIG. 6 is a cross-sectional view illustrating another semiconductor package.

### DETAILED DESCRIPTION

Example embodiments will be described more fully with reference to the accompanying drawings, in which example embodiments are shown. Embodiments described herein are provided as examples, and thus, the present disclosure is not limited thereto, and may be realized in various other forms. Each embodiment provided in the following description is not excluded from being associated with one or more features of another example or another embodiment also provided herein or not provided herein but consistent with the present disclosure. In the drawings, sizes of elements, components, layers, and regions may be exaggerated for sake of clarity. In this specification, a single form “a” and “an” is intended to encompass a plural form as well, unless the context clearly indicates otherwise.

For ease of description, spatially relative terms, such as “beneath,” “below,” “lower,” “above,” “upper,” and the like, may be used herein to describe one element's relationship to other elements as illustrated in the drawings. It will be understood that the spatially relative terms are also intended to encompass different orientations of the device in use or operation, in addition to the orientation(s) depicted in the drawings. For example, if the device in the drawings is turned over, an element described as “below” or “beneath” other elements would then be oriented “above” the other elements. Thus, the term “below” can encompass both an orientation of “above” and “below”. The device may be oriented otherwise (e.g., rotated 90 degrees or at other orientations), and the spatially relative descriptors used herein are interpreted accordingly.

It will be understood that when an element or layer is referred to as being “on,” “connected to” or “coupled to” another element or layer, it can be directly on, connected or coupled to the other element or layer, or intervening elements or layers may be present. By contrast, when an element is referred to as being “directly on,” “directly connected to” or “directly coupled to” another element or layer, there are no intervening elements or layers present. Expressions such as “at least one of,” when preceding a list of elements, modify the entire list of elements and do not modify the individual elements of the list. For example, the expression, “at least one of a, b, and c,” should be understood as including only a, only b, only c, both a and b, both a and c, both b and c, or all of a, b, and c.

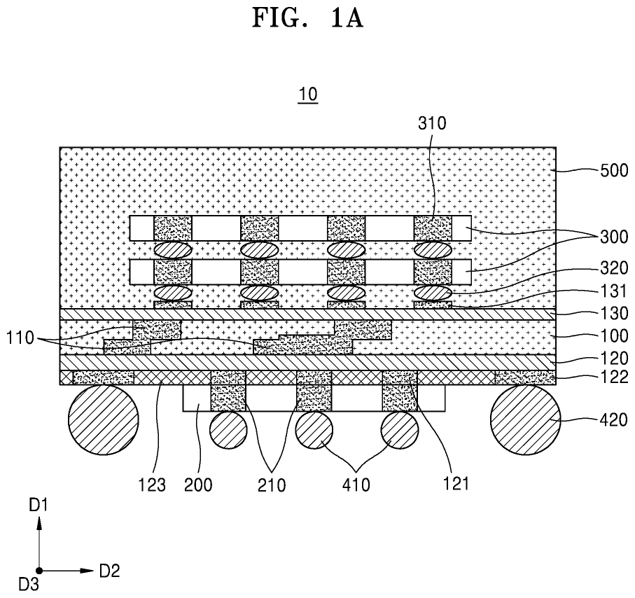

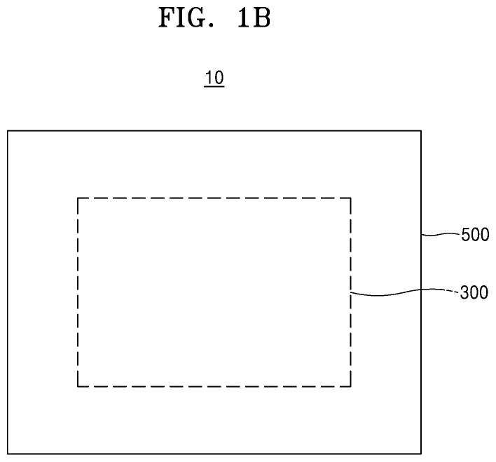

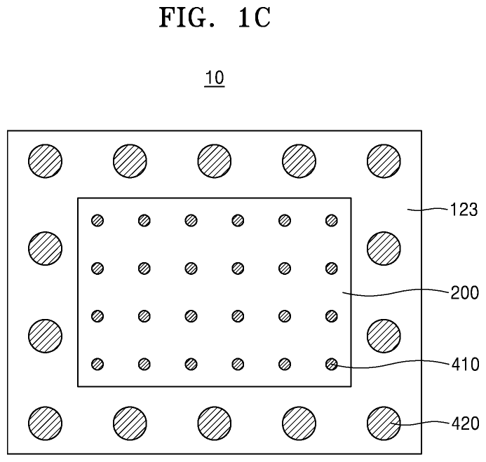

FIG. 1A is a schematic cross-sectional view illustrating a three-dimensional (3D) semiconductor package according to an example embodiment. FIG. 1B is a schematic top view illustrating a 3D semiconductor package according to an example embodiment. FIG. 1C is a schematic bottom view illustrating a 3D semiconductor package according to an example embodiment. As references, FIG. 1B may be a view that is viewed downwardly from above the top of the 3D semiconductor package of FIG. 1A, and FIG. 1C may be a view that is viewed upwardly from below the bottom of the 3D semiconductor package of FIG. 1A.

A three-dimensional (3D) semiconductor package 10 according to an example embodiment may include a package substrate 100, a first redistribution layer 120, a first chip 200, first connection terminals 410, a second redistribution layer 130, and a second chip 300. As illustrated in FIG. 1A, each of the package substrate 100, the first redistribution layer 120, the first chip 200, the second redistribution layer 130, and the second chip 300 may have a first surface (e.g., a lower or bottom surface) and a second surface (e.g., an upper or top surface) opposite to each other in a thickness direction (e.g., a first direction D1) thereof. In addition, each of the package substrate 100, the first redistribution layer 120, the first chip 200, the second redistribution layer 130, and the second chip 300 may have lateral surfaces (e.g., side surfaces) connected between the first surface (e.g., the lower or bottom surface) and the second surface (e.g., the upper or top surface) thereof.

The package substrate 100 may have a lower surface and an upper surface opposite to each other in the first direction D1. The package substrate 100 may be formed with a plurality of electrical paths 110 therein. At least some of the electrical paths 110 may extend between the lower and upper surfaces of the package substrate 100. The electrical paths 110 extending between the lower and upper surfaces of the package substrate 100 may provide electrical routings electrically connecting an electrical element (e.g., a wiring, a conductive member, a chip, and/or the like) disposed above the package substrate 100 and an electrical element (e.g., a wiring, a conductive member, a chip, and/or the like) disposed below the package substrate 100. According to an example embodiment, the electrical paths 110 extending between the lower and upper surfaces of the package substrate 100 may have relatively smaller path lengths, for example, compared with other or remaining ones of the electrical paths 110 of the package substrate 100. When the electrical paths 110 have relatively smaller path lengths, a transmission loss of electric signals due to resistances, etc., of the electrical paths 110 may be reduced, and a transmission rate of electric signals between the electrical elements connected through the electrical paths 110 may be increased.

Although not particularly illustrated, the package substrate 100 may include a plurality of wiring layers and a plurality of insulation layers alternatively stacked, and a plurality of vias disposed in the insulation layers. The insulation layers may electrically insulate different wiring patterns of the same wiring layer from each other, and may insulate wiring patterns of different wiring layers from each other. Each via may penetrate through one or more insulation layers to connect corresponding wiring patterns in different wiring layers to each other. The wiring patterns connected through the one or more vias may form the electrical paths 110 of the package substrate 100, together with the vias. In an example embodiment, each of the wiring layers and the vias may include, for example, at least one of a metal, a metal alloy, and a conductive metal nitride, and may be formed as a single-layered or multi-layered structure. The insulation layers may be formed of an insulating material. The package substrate 100 may be a substrate capable of being used for a dual-face mounting, and may be a commonly-used substrate for semiconductor packaging in the art. In an example embodiment, the package substrate 100 may be a plastic package substrate, a built-up package substrate, or the like, however example embodiments are not limited thereto. According to an example embodiment of the present disclosure, the package substrate 100 may not be a silicon (Si) substrate or a Si interposer, as described below. That is, in an example embodiment, the package substrate 100 may be a substrate other than a silicon substrate or a silicon interposer.

The first redistribution layer 120 may be formed on the lower surface of the package substrate 100. For example, the first redistribution layer 120 may be directly formed on the lower surface of the package substrate 100. For example, an upper surface of the first redistribution layer 120 facing the package substrate 100 may contact the lower surface of the package substrate 100.

Although not particularly illustrated, the first redistribution layer 120 may include at least one wiring layer and at least one insulation layer alternatively stacked, to redistribute (e.g., fan-in or fan-out) connection terminals of an electrical element that is connected to the first redistribution layer 120. When the first redistribution layer 120 includes a plurality of wiring layers and a plurality of insulation layers alternatively stacked, the first redistribution layer 120 may further include vias used to interconnect the plurality of wiring layers. The wiring layers and the vias of the first redistribution layer 120 may include, for example, at least one of a metal, a metal alloy, and a conductive metal nitride. The insulation layers of the first redistribution layer 120 may include an insulating material.

The first redistribution layer 120 may be electrically connected to the package substrate 100. For example, the wiring layers of the first redistribution layer 120 may be connected to the electrical paths 110 of the package substrate 100 to allow an electrical interconnection between the first redistribution layer 120 and the package substrate 100. The first redistribution layer 120 may be electrically connected to a second redistribution layer 130, which is to be described later, by the electrical paths 110 of the package substrate 100, so as to be electrically interconnected with the second redistribution layer 130.

The first chip 200 may be provided on a lower surface of the first redistribution layer 120. The first chip 200 may be electrically connected to the first redistribution layer 120. The first chip 200 may be electrically connected to the package substrate 100 through the first redistribution layer 120. The first chip 200 may be mounted in a flip-chip form on the lower surface of the first redistribution layer 120. The first chip 200 may exchange electric signals with the outside through the first redistribution layer 120, and the first chip 200 may exchange electric signals with the outside through the first redistribution layer 120 and the package substrate 100. As used herein, the term “exchange” may refer to transmit and/or receive. Accordingly, the first chip 200 may transmit and/or receive electric signals with the outside through the first redistribution layer 120 and the package substrate 100.

Referring to FIG. 1A, the first chip 200 may include first through silicon vias (TSVs) 210. The first TSVs 210 may be formed in the first chip 200 by a through-silicon-via process, and penetrate through the first chip 200. For example, the first TSVs 210 may penetrate through active and inactive surfaces of the first chip 200. When the first chip 200 is electrically connected to the first redistribution layer 120, conductive pads (not shown) disposed on the active surface of the first chip 200 may be electrically connected to the first redistribution layer 120, and ends of the first TSVs 210 included in the first chip 200, which are close to the first redistribution layer 120, may be electrically connected to the first redistribution layer 120. The first redistribution layer 120 may electrically connect and/or fan-out the conductive pads and/or the first TSVs 210 of the first chip 200 to the package substrate 100.

Referring to FIGS. 1A and 1C, the first connection terminals 410 may be electrically connected to the other ends of the first TSVs 210, which are away from the first redistribution layer 120. The first connection terminal 410 may be disposed on the other ends of the first TSVs 210 on a side of the inactive surface of the first chip 200. The first connection terminals 410 may be used for an external connection. For example, the first connection terminal 410 may be exposed below the 3D semiconductor package 10 for an electrical connection of the 3D semiconductor package 10 to the outside (e.g., an external substrate). In this case, the first chip 200 may also directly exchange electric signals with the external substrate through the first TSVs 210 and the first connection terminals 410.

The first connection terminal 410 may have a relatively small size. For example, the first connection terminal 410 may have a size in a range of from 50 μm to 100 μm. In an example embodiment, as illustrated in FIG. 1A, the first connection terminals 410 may be solder balls. In this case, a diameter of the first connection terminal 410 may be in a range of from 50 μm to 100 μm. In another example embodiment, the first connection terminals 410 may be bumps. In this case, a length (e.g., in a second direction D2 or a third direction D3) and/or a height (e.g., in the first direction D1) of the first connection terminal 410 may be in a range of from 50 μm to 100 μm. However, the example embodiments are not limited thereto, and the type and the size of the first connection terminals 410 may vary, for example, depending on an interface specification of an external substrate to be connected. As illustrated in FIG. 1C, the first connection terminals 410 may be arranged on a lower surface of the first chip 200 in a matrix form, but example embodiments are not limited thereto. For example, a planar layout of the first connection terminals 410 on the lower surface of the first chip 200 may vary depending on an interface specification of an external substrate to be connected, and an arrangement of the first TSVs 210 of the first chip 200 may vary accordingly.

According to an example embodiment, the first chip 200 may be a logic chip. For example, the first chip 200 may include at least one of a logic die and a system-on-chip (SoC). When the first chip 200 of the example embodiment is a logic chip, it may generally have a relatively large number of outwards-connecting terminals to satisfy function and/or performance requirements thereof. In this case, the conductive pads formed on the active surface of the first chip 200 and the first TSVs 210 exposed at the active surface of the first chip 200 may have generally a relatively small size and a relatively small pitch. For example, when viewed from a side of the active surface of the first chip 200, the conductive pads and the first TSVs 210 may be arranged in a pitch less than or equal to 50 μm. In an example embodiment, when the first redistribution layer 120 is formed by a micrometer-scale process, the first chip 200 may be directly in electrical connection with the wiring layers of the first redistribution layer 120 by a bonding method. For example, the bonding method used herein may be, but not limited to, a metal-to-metal bonding (e.g., a Cu (copper)-to-Cu bonding).

According to an example embodiment, referring to FIG. 1A, the 3D semiconductor package 10 may further include first connection members 121 disposed between the first redistribution layer 120 and the first chip 200. As illustrated in FIG. 1A, the first connection members 121 may connect the first TSVs 210 of the first chip 200 to the first redistribution layer 120. Although not illustrated, the first connection members 121 may also connect the conductive pads of the first chip 200 disposed on the active surface thereof to the first redistribution layer 120. That is, the first connection members 121 may electrically connect the first chip 200 to the first redistribution layer 120.

The first connection members 121 may be micro-bumps. As used herein, the term “micro-bump” may refer to a bump of which a size (e.g., a length in the second direction D2 or the third direction D3) is less than or equal to 50 μm. In addition, the first connection members 121 as the micro-bumps may be disposed between the first chip 200 and the first redistribution layer 120 in a pitch less than or equal to 50 μm, so as to match a requirement for a relatively high density of electrical connections of the first chip 200. In addition, heights of the first connection members 121 as the micro-bumps in the first direction D1 may be less than or equal to 10 μm. When the first connection members 121 as the micro-bumps are used to connect the first chip 200 and the first redistribution layer 120, it may not be necessary to form the first redistribution layer 120 by a micrometer-scale process. As such, process difficulties and manufacturing cost may be reduced while the requirement for electrical connections of the first chip 200 may be achieved.

In an example embodiment, the first connection members 121 may be formed as a wiring layer, together with the first redistribution layer 120. That is, the first connection members 121 may be the outermost wiring layer (the lowermost wiring layer as illustrated in FIG. 1A) of the redistribution layer 120. Wiring patterns of the wiring layer may be formed to have a size and/or a pitch less than or equal to 50 μm. However, example embodiments are not limited thereto. For example, as to be described later, the first connection members 121 may be formed on the lower surface of the first redistribution layer 120 by a separate process after the first redistribution layer 120 is formed.

When the first chip 200 and the first redistribution layer 120 are provided with the first connection members 121 therebetween, as illustrated in FIG. 1A, the 3D semiconductor package 10 may further include a non-conductive film (NCF) 123. The NCF 123 may fill a space between the first chip 200 and the first redistribution layer 120, and may be disposed around so as to surround the first connection members 121. In an example embodiment, the NCF 123 may completely fill the space between the first chip 200 and the first redistribution layer 120, and be disposed on or cover side surfaces of the first connection members 121. The NCF 123 may be provided on the lower surface of the first redistribution layer 120 by a laminating process before the first chip 200 is mounted on the first redistribution layer 120, and this will be described later. Through the NCF 123, the first connection members 121 may be protected, and connection stability and reliability of the first chip 200 and the first redistribution layer 120 may be improved. In addition, a connection layer composed of the first connection members 121 and the NCF 123 may have a relatively small thickness (e.g., a thickness less than or equal to 10 μm), and thus, a thickness of the 3D semiconductor package 10 in the first direction D1 (e.g., a vertical direction) may be relatively reduced, so that a vertical size of the 3D semiconductor package 10 may be relatively reduced.

Referring to FIG. 1A, the second redistribution layer 130 may be formed on the upper surface of the package substrate 100. For example, the second redistribution layer 130 may be directly formed on the upper surface of the package substrate 100. For example, a lower surface of the second redistribution layer 130 facing the package substrate 100 may contact the upper surface of the package substrate 100. The second redistribution layer 130 may have a configuration similar to that of the first redistribution layer 120. The second redistribution layer 130 may redistribute (e.g., fan-in or fan-out) connection terminals of an electrical element connected to the second redistribution layer 130 through wiring layers thereof.

The second redistribution layer 130 may be electrically connected to the package substrate 100. For example, the wiring layers of the second redistribution layer 130 may be connected to the electrical paths 110 of the package substrate 100 to allow the second redistribution layer 130 and the package substrate 100 to be electrically interconnected to each other. The second redistribution layer 130 may be electrically connected to the first redistribution layer 120 through the electrical paths 110 of the package substrate 100, so as to be electrically interconnected with the first redistribution layer 120. That is, in an example embodiment, electrical routings may be formed across the first redistribution layer 120, the package substrate 100, and the second redistribution layer 130.

The second chip 300 may be provided on an upper surface of the second redistribution layer 130. The second chip 300 may be electrically connected to the second redistribution layer 130. The second chip 300 may be electrically connected to the package substrate 100 through the second redistribution layer 130. In an example embodiment, the second chip 300 may be mounted on the upper surface of the second redistribution layer 130 in a flip-chip form. For example, conductive pads (not shown) disposed on an active surface of the second chip 300 may be electrically connected to the second redistribution layer 130, and electrically connected and/or fanned-out to the electrical paths 110 of the package substrate 100 through the second redistribution layer 130.

In an example embodiment, the second chip 300 may exchange electric signals with the first chip 200 through the second redistribution layer 130, the package substrate 100, and the first redistribution layer 120. In an example embodiment, the second chip 300 may exchange electric signals with the outside through the second redistribution layer 130, the package substrate 100, and the first redistribution layer 120. In an example embodiment, the second chip 300 may exchange electric signals with the outside through the second redistribution layer 130, the package substrate 100, the first redistribution layer 120, the first TSVs 210, and the first connection terminals 410.

According to an example embodiment, the second chip 300 may be provided in single or plural. When the second chip 300 includes a plurality of second chips 300, as illustrated in FIG. 1A, the plurality of second chips 300 may be sequentially stacked on the upper surface of the second redistribution layer 130 in the first direction D1 (e.g., the vertical direction) to form a stack. In the stack, a lowermost second chip 300 may be electrically connected to the second redistribution layer 130, for example, mounted on and electrically connected to the second redistribution layer 130 in a flip-chip form. In the stack, an upper second chip 300 may be electrically connected to a lower second chip 300, for example, mounted on and electrically connected to the lower second chip 300 in a flip-chip form. The plurality of second chips 300 included in the stack may be electrically connected to each other, and may further be electrically connected to the second redistribution layer 130. Although FIG. 1A illustrates a stack including two second chips 300, example embodiments are not limited thereto. For example, a stack that includes three or more second chips 300 sequentially stacked on and electrically connected to each other may be provided on the second redistribution layer 130.

In the stack including the plurality of second chips 300, the stacked second chips 300 may be electrically connected to each other by a through-silicon-via (TSV) method. As illustrated in FIG. 1A, each of the second chips 300 may include therein a plurality of second through silicon vias (TSVs) 310 penetrating through active and inactive surfaces thereof, and the second TSVs 310 of the second chips 300 adjacent to each other may be electrically connected to each other in a one-to-one correspondence form. For example, as illustrated in FIG. 1A, corresponding ones of the second TSVs 310 of the adjacent second chips 300 may be connected to each other through conductive terminals 320 provided between the adjacent second chips 300. In an example embodiment, the conductive terminals 320 may be disposed on the active surface of each of the second chips 300 and electrically connected to corresponding ones of the second TSVs 310, and may be bumps or solder balls. Although FIG. 1A illustrates that each of the second chips 300 includes four second TSVs 310, this is merely an example, and the example embodiments are not limited thereto. For example, each of the second chips 300 may include three or fewer, or five or more, second TSVs 310. In addition, although FIG. 1A illustrates that an uppermost second chip 300 in the stack is disposed to have second TSVs 310, the example embodiments are not limited thereto. For example, the uppermost second chip 300 in the stack may not include the second TSVs 310.

In an example embodiment according, the second chip 300 may be a cache chip. In an example embodiment, the cache chip may be at least one of a high bandwidth memory (BHM) and a dynamic random access memory (DRAM). In an example embodiment in which the second chip 300 is a high bandwidth memory (BHM) or a dynamic random access memory (DRAM) the second chip 300 may generally have a relatively large number of outwards-connecting terminals to satisfy function and/or performance requirements thereof. In this case, the conductive terminals 320 formed on the active surface of the second chip 300 may generally have a relatively small size and a relatively small pitch. For example, when viewed from a side of the active surface of the second chip 300, the conductive terminals 320 may be arranged in a pitch less than or equal to 50 μm. In an example embodiment, when the second redistribution layer 130 is formed by a micrometer-scale process, the conductive terminals 320 of the second chip 200 (or the lowermost second chip 300 from among the stacked second chips 300) may be directly in electrical connection with wiring patterns of the uppermost wiring layer of the second redistribution layer 130 by a method of bonding, back-welding, or the like.

According to an example embodiment, referring to FIG. 1A, the 3D semiconductor package 10 may further include second connection members 131 provided between the second redistribution layer 130 and the second chip 300 (or the lowermost second chip 300). As illustrated in FIG. 1A, the second connection members 131 may connect the conductive terminals 320 of the lowermost second chip 300 to the second redistribution layer 130. That is, the second connection members 131 may electrically connect the second chip 300 to the second redistribution layer 130.

The second connection members 130 may be micro-bumps. The second connection members 131 may have a configuration and properties similar to those of the first connection members 121 that are the micro-bumps as described above. When the second chip 300 (or the lowermost second chip 300) is connected to the second redistribution layer 130 by using the second connection members 131, it may not be necessary to form the second redistribution layer 130 by a micrometer-scale process. As such, process difficulties and manufacturing cost may be reduced while the requirement for electrical connections of the second chip 200 may be achieved.

Similar to the first connection members 121 and the first redistribution layer 120, the second connection members 131 may be formed as the outermost wiring patterns (the uppermost wiring layer as illustrated in FIG. 1A) of the second redistribution layer 130 in a process for the second redistribution layer 130, or may be formed on the upper surface of the second redistribution layer 130 by a separate process after the second redistribution layer 130 is formed.

Referring to FIG. 1A together with FIGS. 1B and 1C, when viewed in a plane defined by the second and third directions D2 and D3 substantially perpendicular to the first direction D1 and intersecting with each other (i.e., when viewed in a plan view), the first and second chips 200 and 300 may be disposed within the package substrate 100, for example, disposed within a periphery or border of the package substrate 100. That is, when viewed in a plan view, a periphery of the package substrate 100 may be around and surround the first chip 200 and may be around and surround the second chip 300. In an example embodiment, as illustrated in FIG. 1A, lengths of the package substrate 100 in the second and third directions D2 and D3 may be greater than lengths of the first chip 200 in the second and third directions D2 and D3. The lengths of the package substrate 100 in the second and third directions D2 and D3 may be greater than lengths of the second chip 300 in the second and third directions D2 and D3. That is, side surfaces of the package substrate 100 may protrude beyond side surfaces of the first chip 200 and side surfaces of the second chip 300. In addition, the first and second chips 200 and 300 may overlap in the first direction D1 (e.g., the vertical direction) with a portion of the package substrate 100 interposed therebetween. In an example embodiment, the second direction D2 may be a horizontal direction and the third direction D3 may be another horizontal direction. According to an example embodiment, the first and second chips 200 and 300 may be electrically connected to each other with relatively short electrical routings by the first redistribution layer 120, the package substrate 100, and the second redistribution layer 130 interposed therebetween. This may improve an access/call speed of the first chip 200 to the second chip 300, thereby improving a transmission rate of electric signals between/among the components of the 3D semiconductor package 10.

Referring to FIG. 1A together with FIG. 1C, the 3D semiconductor package 10 may further include a plurality of second connection terminals 420. The plurality of second connection terminals 420 may be disposed on the lower surface of the first redistribution layer 120. The plurality of second connection terminals 420 may be disposed at an outer side(s) of the first chip 200 and spaced apart from the first chip 200. As illustrated in FIG. 1C, the second connection terminals 420 may be around and surround the first connection terminals 410 on the lower surface of the first redistribution layer 120. That is, the plurality of second connection terminals 420 may be arranged along an edge(s) of the lower surface of the first redistribution layer 120 to surround the first connection terminals 410. As illustrated in FIGS. 1A and 1C, the second connection terminals 420 may be solder balls having a relatively large size. For example, when measured in the first direction D1, heights of the second connection terminals 420 may be greater than the heights of the first connection terminals 410, and when measured in the second or third direction D2 or D3, lengths of the second connection terminals 420 may be greater than the lengths of the first connection terminals 410. In an example embodiment, the height of the second connection terminal 420 may be substantially equal to a sum of a height of the first chip 200 and the height of the first connection terminal 410. In an example embodiment, a size (e.g., diameter, height, and/or length) of the second connection terminal 420 may be in a range of from 100 μm to 500 μm, but the example embodiments are not limited thereto, and the size of the second connection terminals 420 may vary depending on an interface specification of an external substrate to be connected. In addition, unlike the planar layout of the second connection terminals 420 on the first redistribution layer 120 as illustrated in FIG. 1C, the planar layout of the second connection terminals 420 may also vary depending on an interface specification of an external substrate to be connected. In the 3D semiconductor package 10, there may be a warpage of the package substrate 100, and a degree of the warpage is generally maximum at edges of the package substrate 100. By disposing the second connection terminals 420 having a relatively large size, a non-wet issue due to the warpage (e.g., a non-wet issue occurring while the 3D semiconductor package 10 is mounted on an external substrate) may be prevented or mitigated by using a larger surface tension provided by the second connection terminals 420.

The plurality of second connection terminals 420 may include one or more transmission terminals used to transmit electric signals and/or one or more dummy terminals not used to transmit electric signals. In an example embodiment, the plurality of second connection terminals 420 may include one or more second connection terminals 420, which are electrically connected to the first redistribution layer 120, or which are electrically connected to the package substrate 100 through the first redistribution layer 120. In an example embodiment, the plurality of second connection terminals 420 may include one or more second connection terminals 420, which are not electrically connected to the first redistribution layer 120, or which are not electrically connected to the package substrate 100.

The transmission terminals of the second connection terminals 420 may be disposed on the first redistribution layer 120, and electrically connected to the first redistribution layer 120 or electrically connected to the package substrate 100 through the first redistribution layer 120. Compared with the first connection terminals 410, the second connection terminals 420 as the transmission terminals may be more suitable to transmit electric signals of relatively high magnitudes (e.g., high currents and/or high voltages) due to their relatively large size. As a result, stability and reliability of an electrical connection of the 3D semiconductor package 10 with an external substrate may be improved.

The dummy terminals of the second connection terminals 420 may be disposed on the first redistribution layer 120, and may be electrically isolated or electrically floated. When the 3D semiconductor package 10 is mounted on an external substrate, the second connection terminals 420 serving as dummy terminals may be connected to the external substrate and may function as supports and thermal conductors. For example, the dummy terminals may be connected to the outermost wiring patterns of the first redistribution layer 120, and the wiring patterns connected to the dummy terminals may be isolated patterns that are not connected to other wiring patterns, so that the dummy terminals may be electrically isolated from the other components. As another example, the dummy terminals may be electrically connected to the first redistribution layer 120 (alternatively, electrically connected to the package substrate 100 through the first redistribution layer 120), but may not be applied with an electric signal, so that the dummy terminals may be electrically floated. In an example embodiment, the electrically-floated dummy terminals may further be used as a redundancy for the transmission terminals.

The plurality of second terminals 420 may be directly connected to the first redistribution layer 120, but the example embodiments are not limited thereto. According to an example embodiment of the present disclosure, the 3D semiconductor package 10 may further include a plurality of third connection members 122. The plurality of third connection members 122 may be provided between the first redistribution layer 120 and the plurality of the second connection terminals 420, respectively, and connect the plurality of second connection terminals 420, respectively, to the first redistribution layer 120. The third connection members 122 may be substantially the same as or similar to the first connection members 121 except for having lengths greater than those of the first connection members 121. For example, the third connection member 122 may have a height less than or equal to 10 μm in the first direction D1, and the third connection member 122 may have a length, which matches the second connection terminal 420, in the second or third direction D2 or D3, for example, a length in a range of from 100 μm to 500 μm. As illustrated in FIG. 1A, the NCF 123 filling between the first chip 200 and the first redistribution layer 120 may extend along the lower surface of the first redistribution layer 120 to encircle the third connection members 122. The NCF 123 may protect the third connection members 122. Although not illustrated, in an example embodiment, the NCF 123 may further be disposed on and cover portions of lower surfaces of the third connection members 122.

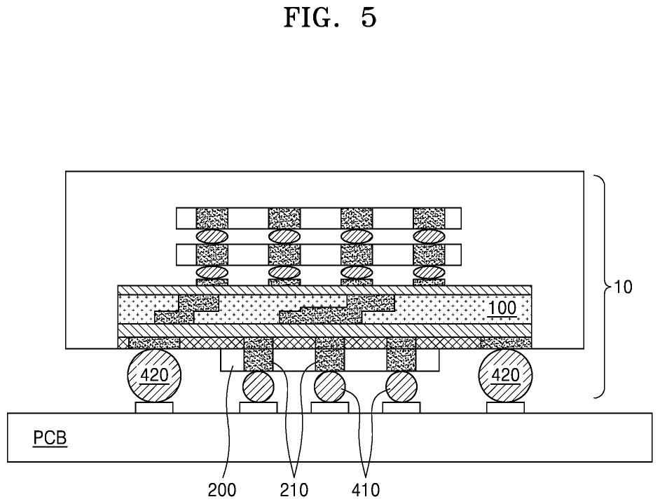

Referring to FIGS. 1A and 1B, the 3D semiconductor package 10 may further include a molding layer 500. The molding layer 500 may include a common material for semiconductor packaging in the art, for example, an epoxy molding compound (EMC). At least a portion of the molding layer 500 may cover the second chip 300 and the second redistribution layer 130 on the upper surface of the package substrate 100. As illustrated in FIG. 1A, the second chips 300 may be completely covered by the molding layer 500, the upper surface of the second redistribution layer 130 may be covered by the molding layer 500, and side surfaces of the molding layer 500 may be substantially aligned with the side surfaces of the package substrate 100 and side surfaces of the second redistribution layer 130. However, the example embodiments are not limited thereto. For example, although not illustrated, the second redistribution layer 130 may be disposed on only a portion of the upper surface of the package substrate 100. In this case, the molding layer 500 may further be disposed on or cover the side surfaces of the second redistribution layer 130 and contact a remaining portion of the upper surface of the package substrate 100. In addition, as illustrated in FIG. 5 to be described further below, the molding layer 500 may further extend beyond the side surfaces of the package substrate 100 and extend downwardly to be disposed on or cover the second redistribution layer 130, the side surfaces of the package substrate 100, and side surfaces of the first redistribution layer 120.

Referring again to FIGS. 1A to 1C, the 3D semiconductor package 10 according to the example embodiments may include the first chip 200, the package substrate 100, and the second chip(s) 300 sequentially stacked in the first direction D1 and electrically connected to each other, wherein the first chip 200 includes the first TSVs 210 disposed therein, and the first connection terminals 410 are disposed on and connected to the lower ends of the first TSVs 210. Therefore, the 3D semiconductor package 10 may form electrical routings among the second chip(s) 300 (such as the cache chip(s)), the package substrate 100, the first chip 200 (such as the logic chip), and the first connection terminals 410 in the vertical direction, and may be directly connected to an external substrate by the formed electrical routings and via the first connection members 410. As a result, transmission paths for electric signals of the 3D semiconductor package 10 may be effectively shortened, so that the transmission rate of electric signals of the 3D semiconductor package 10 may be improved. In addition, the package density of the 3D semiconductor package 10 may be increased, and the size (e.g., a horizontal size) of the 3D semiconductor package 10 may be reduced.

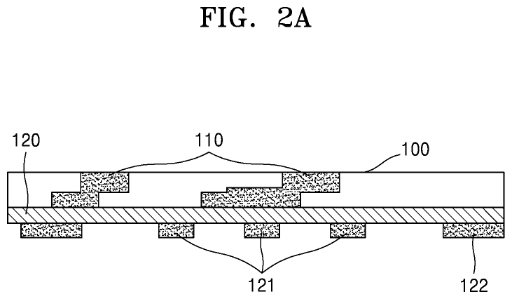

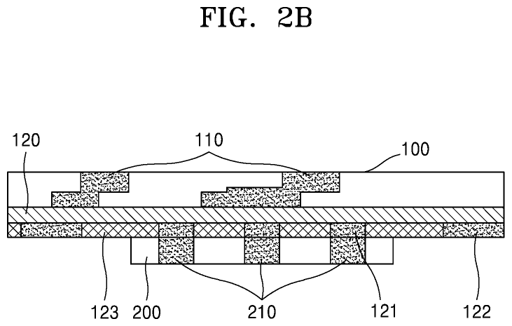

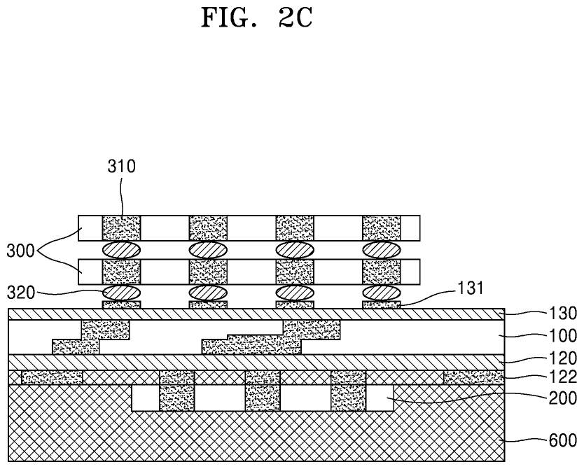

FIGS. 2A to 2C are schematic cross-sectional views illustrating stages of a method of manufacturing a 3D semiconductor package according to an example embodiment. For convenience of illustration and description, FIGS. 2A to 2C will be described with the same device/component orientations as those of FIG. 1A, but it should be understood that the orientations of the devices/components illustrated in FIGS. 2A to 2C may be adjusted (e.g., turned over) if necessary in an actual manufacturing process.

Referring to FIG. 2A, a package substrate 100 formed with electrical paths 110 therein may be prepared. The package substrate 100 may be a common substrate for semiconductor packaging in the art, for example, but not limited to, a plastic package substrate or a built-up package substrate. The package substrate 100 may be a substrate other than a Si substrate or a Si interposer. That is, for example, the package substrate 100 may be formed by a process in micrometer-scale or above, without a process in nanometer-scale. As a result, the package substrate 100 may have a low manufacturing cost and may have a high yield.

A first redistribution layer 120 may be formed on a lower surface of the package substrate 100. As is conventional in the art, the first redistribution layer 120 may be formed on the lower surface of the package substrate 100 by a deposition and etching process. The first redistribution layer 120 may include at least one wiring layer and at least one insulation layer. The wiring layer of the first redistribution layer 120 closest to the package substrate 100 may be connected to corresponding ones of the electrical paths 110 of the package substrate 100.

After the first redistribution layer 120 is formed, first connection members 121 may be formed on a lower surface of the first redistribution layer 120. The first connection members 121 may be formed by a deposition and etching process. The first connection members 121 may be connected to the wiring layer of the first redistribution layer 120 farthest away from the package substrate 100, and may be arranged on the lower surface of the first redistribution layer 120 in a pitch less than or equal to 50 μm. In addition, the first connection members 121 may be micro-bumps having lengths less than or equal to 50 μm and heights less than or equal to 10 μm. In an example embodiment, the first connection members 121 may include a commonly-used material (e.g., a metal, a metal alloy, or the like) for bumps in the art.

In an example embodiment, third connection members 122 may further be formed at an outer side of the first connection members 121 on the lower surface of the first redistribution layer 120. The third connection members 122 may be formed together with the forming of the first connection members 121. The third connection members 122 may be connected to the wiring layer of the first redistribution layer 120 farthest away from the package substrate 100, and may be formed to surround the first connection members 121 on the lower surface of the first redistribution layer 120. In an example embodiment, in the forming of the first redistribution layer 120, some of wiring patterns on which the third connection members 122 are to be formed may be formed to be electrically isolated from the other wiring patterns.

Thereafter, referring to FIG. 2B, a non-conductive film (NCF) 123 may be provided on the lower surface of the first redistribution layer 120. The NCF 123 may cover the first connection members 121 on the first redistribution layer 120. In an example embodiment, the NCF 123 may further cover the third connection members 122. In an example embodiment, the NCF 123 may expose portions or the entirety of lower surfaces of the third connection members 122.

Sequentially, a first chip 200 including first through silicon vias (TSVs) 210 may be mounted on the first connection members 121. For example, the first chip 200 may be mounted on the first connection members 121 in a flip-chip form. When the first chip 200 is mounted on the first connection members 121, the first TSVs 210 of the first chip 200 and conductive pads disposed on an active surface of the first chip 200 may be aligned with corresponding ones of the first connection members 121, respectively. In addition, the first TSVs 210 and the conductive pads of the first chip 200 may be coupled to the corresponding ones of the first connection members 121 by a thermal compression bonding method. In this process, the NCF 123 may be pressed by the pressure and laterally flow to allow the contacting and bonding between the first TSVs 210 and the conductive pads of the first chip 200, and the corresponding ones of the first connection members 121. In addition, the pressed NCF 123 may fully fill a space between the first chip 200 and the first redistribution layer 120, and surround and cover side surfaces of the first connection members 121.

In addition, referring to FIG. 2C, a protective layer 600 may be formed to cover the first chip 200, the NCF 123, and the third connection members 122. The protective layer 600 may protect the structure that has formed on the lower surface of the package substrate 100, during a process for forming a structure located on an upper surface of the package substrate 100. The protective layer 600 may be formed of a photo-sensitive polymer material, and may be removed by an irradiation of UV light. For example, the protective layer 600 may be a protective tape formed of photo-sensitive polyimide (PI).

Sequentially, a second redistribution layer 130 may be formed on the upper surface of the package substrate 100. Then, second connection members 131 may be formed on an upper surface of the second redistribution layer 130. Processes for forming the second redistribution layer 130 and the second connection members 131 may be substantially the same as or similar to those for forming the first redistribution layer 120 and the first connection members 121. In addition, the second connection members 131 may include the same material as that of the first connection members 121.

Sequentially, a second chip 300 may be prepared. When the second chip 300 is provided in single, a second chip 300, on an active surface of which conductive terminals 320 are formed, may be prepared. When the second chip 300 is provided in plural, a plurality of second chips 300, each of which is formed with second through silicon vias (TSVs) 310 therein and formed with conductive terminals 320 electrically connected to ends of the second TSVs 310 on an active surface thereof, may be prepared.

Sequentially, the second chip 300 may be mounted on the second connection members 131. For example, the second chip 300 may be mounted on the second connection members 131 in a flip-chip form, and the conductive terminals 320 of the second chip 300 may be coupled to the second connection members 131 by using a method of thermal compression bonding, back-welding, or the like.

When the second chip 300 is provided in plural, the plurality of second chips 300 may be sequentially stacked in a flip-chip form, wherein the lowermost one of the second chips 300 may be mounted on the second connection members 131 through the conductive terminals 320 thereof, and an upper second chip 300 from among the others of the second chips 300 may be mounted on the second TSVs 310 of one of the second chips 300 located thereunder through the conductive terminals 320 thereof, and then, by using a method of thermal compression bonding, back-welding, or the like, the conductive terminals 320 of the lowermost second chip 300 may be coupled to the second connection members 131, and the conductive terminals 320 of the other second chips 300 may be coupled to corresponding second TSVs 310. As a result, a stack including the plurality of second chips 300 may be formed.

Referring back to FIG. 1A, a molding layer 500 may be formed to cover the second chip 300 and the second redistribution layer 130. The molding layer 500 may be formed of an epoxy molding compound (EMC). In an example embodiment, unlike that illustrated in FIG. 2C, the protective layer 600 may extend beyond side surfaces of the package substrate 100 in addition to being disposed on or covering the first chip 200, the NCF 123, and the third connection members 122. In this case, the molding layer 500 may also be formed to cover the entire structure over the protective layer 600, and thus, the molding layer 500 may further be disposed on or cover side surfaces of the second redistribution layer 130, the side surfaces of the package substrate 100, and side surfaces of the first redistribution layer 120 (see FIG. 5).

Referring again to FIG. 1A, after the molding layer 500 is formed, the protective layer 600 may be removed. For example, the protective layer 600 may be removed after being irradiated by using UV light. After the protective layer 600 is removed, a lower surface of the first chip 200 and the third connection members 122 may be exposed.

Thereafter, first connection terminals 410 may be disposed at ends of the first TSVs 210 away from the package substrate 100 on the lower surface of the first chip 200. The first connection terminals 410 may be electrically coupled to the first TSVs 210. Then, second connection terminals 420 may be disposed on the third connection members 122. The second connection terminals 420 may be connected to the third connection members 122.

By the processes described above, the 3D semiconductor package 10 as illustrated in FIGS. 1A to 1C may be manufactured.

However, the method of manufacturing the 3D semiconductor package according to the example embodiments are not limited thereto. For example, when at least one of the first and second redistribution layers 120 and 130 is formed by a micrometer-scale process, the forming of the first connection members 121 and/or the forming of the second connection members 131 may be omitted accordingly. For another example, when the second connection terminals 420 are not disposed, the forming of the third connection members 122 may be omitted accordingly.

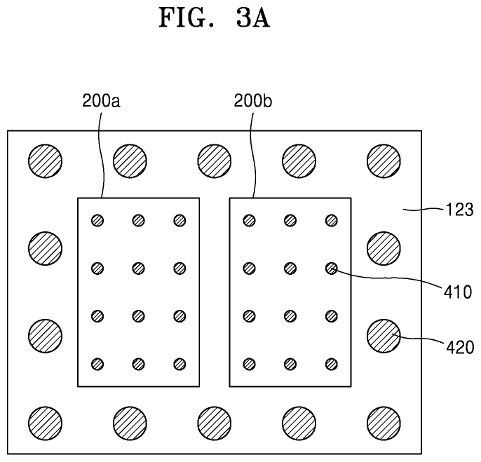

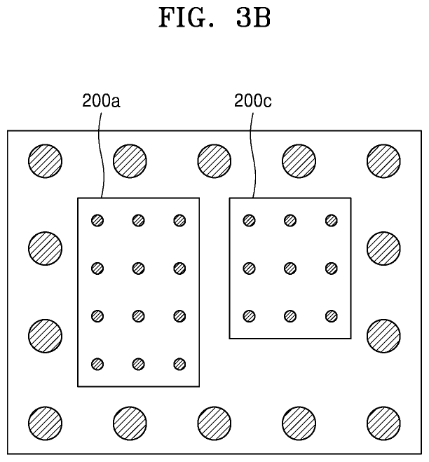

FIGS. 3A and 3B are schematic layout diagrams illustrating a plurality of first chips according to an example embodiment.

Referring to FIGS. 3A and 3B, the example embodiments described herein are different from the above-described example embodiments in that a three-dimensional (3D) semiconductor package may include a plurality of first chips. For simplicity of description, the following description will be given based on the foregoing difference, and the other descriptions of the 3D semiconductor package 10 already given with reference to FIGS. 1A to 1C are omitted accordingly.

Referring to 3A, the 3D semiconductor package may include a plurality of first chips 200a and 200b. The plurality of first chips 200a and 200b are configured to be arranged side by side on a lower surface of a first redistribution layer 120 (see FIG. 1A), and each of the plurality of first chips 200a and 200b may be electrically connected to the first redistribution layer 120. The plurality of first chips 200a and 200b may have substantially the same size. For example, when viewed in the plan view, the plurality of first chips 200a and 200b may have substantially the same area. In an example embodiment, the plurality of first chips 200a and 200b may be logic chips. For example, the plurality of first chips 200a and 200b may be logic chips having the same type as each other.

Referring to FIG. 3B, the 3D semiconductor package may include a plurality of first chips 200a and 200c. The plurality of first chips 200a and 200c are configured to be arranged side by side on a lower surface of a first redistribution layer 120 (see FIG. 1A), and each of the plurality of first chips 200a and 200c may be electrically connected to the first redistribution layer 120. The plurality of first chips 200a and 200c may have different sizes from each other. For example, when viewed in the plan view, the plurality of first chips 200a and 200c may have different areas from each other. In an example embodiment, the plurality of first chips 200a and 200c may be logic chips. For example, the plurality of first chips 200a and 200c may be logic chips having different types from each other.

Referring to FIGS. 3A and 3B, like the first chip 200 in FIG. 1A, each of the first chips 200a, 200b, and 200c may include first through silicon vias (TSVs) 210 therein, and first connection terminals 410 may be disposed on an end of each of the first TSVs 210 away from the first redistribution layer 120. When viewed from a lower surface of each of the first chips 200a, 200b, and 200c, the first connection terminals 410 may have a planar layout of a matrix form, but the example embodiments are not limited thereto. For example, the planar layout of the first connection terminals 410 on the lower surfaces of the first chips 200a, 200b, and 200c may vary depending on an interface specification of an external substrate to be connected thereto.

In addition, referring to FIGS. 3A and 3B, like that illustrated in FIG. 1C, a plurality of second connection terminals 420 may be disposed on the lower surface of the first redistribution layer 120 (see FIG. 1A), and may surround the plurality of first chips 200a and 200b (or 200a and 200c). That is, the first chips 200a and 200b (or 200a and 200c) may be formed in a space surrounded and defined by the first redistribution layer 120 and the second connection terminals 420. In addition, the second connection terminals 420 may be around and surround the first chips 200a and 200b (or 200a and 200c) in various forms, and may vary depending on an interface specification of an external substrate to be connected thereto.

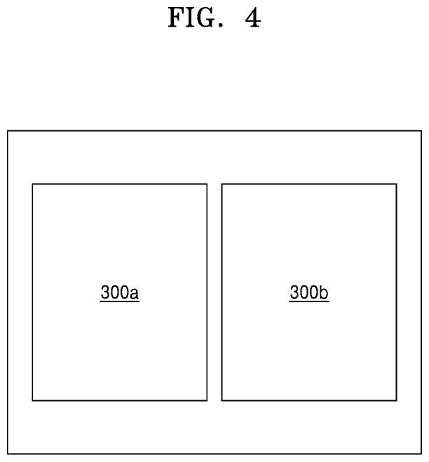

FIG. 4 is a schematic layout diagram illustrating a plurality of second chips according to an example embodiment.

Referring to FIG. 4, the example embodiment described herein is different from the above-described example embodiments in that the three-dimensional (3D) semiconductor package of FIG. 4 may include a plurality of second chips arranged side by side in the plan view. For the sake of simplicity, the following description of the example embodiment of FIG. 4 will be given based on the foregoing difference, and the other descriptions of the 3D semiconductor package 10 already given with reference to FIGS. 1A to 1C may be omitted accordingly.

Referring to FIG. 4, the 3D semiconductor package may include a plurality of second chips 300a and 300b. The plurality of the second chips 300a and 300b may be arranged side by side on an upper surface of a second redistribution layer 130 (see FIG. 1A). Each of the plurality of second chips 300a and 300b may be a single cache chip. In an example embodiment, each of the plurality of second chips 300a and 300b may be a stack of multiple cache chips. For example, the stack of the multiple cache chips may have a structure substantially the same as or similar to that of the stack including the plurality of second chips 300 described with reference to FIG. 1A. In addition, the molding layer 500 as illustrated in FIGS. 1A and 1B may cover the plurality of second chips 300a and 300b. In the example embodiment illustrated in FIG. 4, the plurality of second chips 300a and 300b include two chips, but example embodiments are not limited thereto.

Referring to FIGS. 3A, 3B, and 4 together, the 3D semiconductor package according to the example embodiments may include the multiple logic chips and/or the multiple (or the multi-groups of) cache chips arranged side by side on opposite sides of the package substrate, and as illustrated and described with reference to FIG. 1A, the logic and cache chips and the package substrate interposed therebetween may form relatively short electrical routings in the vertical direction, and may directly communicate with an external substrate through the first connection terminals. Therefore, even if the numbers of the logic chips and the cache chips are increased, the 3D semiconductor package of example embodiments may have an improved transmission rate of electric signals and a reduced size (e.g., a reduced horizontal size).

FIG. 5 is a schematic diagram illustrating a three-dimensional (3D) semiconductor package when being mounted on an external circuit board, according to an example embodiment.

A 3D semiconductor package according to an example embodiment may be mounted on an external substrate (e.g., an external printed circuit board (PCB)). For example, the 3D semiconductor package 10 illustrated in FIG. 5 may have a similar configuration to and substantially the same way of electrical connections as the 3D semiconductor package 10 described with reference to FIG. 1A. As illustrated in FIG. 5, the 3D semiconductor package 10 may include a first chip 200 (such as a logic chip) having through silicon vias (TSVs) 210 and first connection terminals 410 disposed on lower ends of the TSVs 210. The 3D semiconductor package 10 may be connected to corresponding connection pads of the external PCB and exchange electric signals with the external PCB through the first connection terminals 410. In addition, the logic chip provided on one side of a package substrate 100 may be fanned out to the package substrate 100 through a redistribution layer, and electrically connected to one or more cache chips provided on the other side of the package substrate 100 through the package substrate 100, and thereby may access/call to the cache chip(s) by relatively short electrical paths. As such, in the 3D semiconductor package 10, transmission paths for electric signals from “the cache chip(s) to the package substrate to the logic chip to the external PCB” may be formed in a substantially vertical direction, and accordingly, a transmission rate of electric signals between the components of the 3D semiconductor package 10 may be improved, and a transmission rate of electric signals between the 3D semiconductor package 10 and the external PCB, especially a transmission rate of electric signals between the logic chip and the external PCB, may also be improved. In addition, since the logic chip and the cache chip(s) may be disposed within a vertical space at which the package substrate 100 is located, a horizontal size of the 3D semiconductor package 10 may be reduced.

In addition, referring to FIG. 5, the 3D semiconductor package 10 may further include a plurality of second connection terminals 420 disposed at a periphery of the first chip 200 to surround the first chip 200. The second connection terminals 420 may be solder balls having a relatively large size, and thus, the second connection terminals 420 may effectively wet corresponding connection pads of the external PCB even if the package substrate 100 has a warpage occurring at an edge thereof. Accordingly, a non-wet issue due to the warpage of the package substrate 100 may be prevented or mitigated.

In addition, the second connection terminals 420 may include one or more transmission terminals and/or one or more dummy terminals. The second connection terminals 420 when being used as the transmission terminals, may be used to transmit electric signals with relatively high magnitudes and, for example, may be used to receive high currents or high voltages supplied from the external PCB. As such, stability and reliability of an electric signal transmission of the 3D semiconductor package 10 may be improved. The second connection terminals 420 when being used as the dummy terminals, may be used to support the 3D semiconductor package 10, and thus, structural stability of the 3D semiconductor package 10 may be improved. In addition, the second connection terminals 420 when being used as the dummy terminals, may guide and dissipate heat generated by the other components of the 3D semiconductor package 10 to the outside, so that reliability of the 3D semiconductor package 10 may be improved.

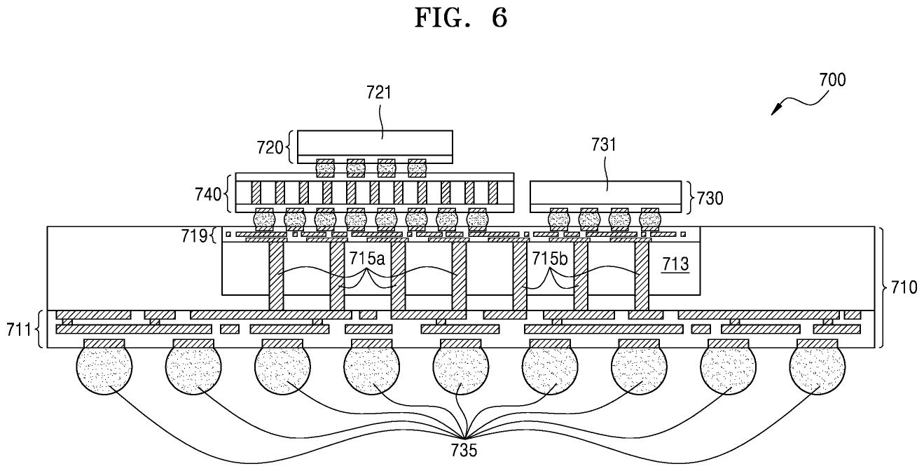

FIG. 6 is a cross-sectional view illustrating another semiconductor package.

Referring to FIG. 6, a semiconductor package 700 may include a substrate 710, a first redistribution layer 719 disposed at an upper portion of the substrate 710, a first silicon (Si) interposer 740 and a first chip structure 730 disposed side by side on the first redistribution layer 719, and a second chip structure 720 disposed on the first Si interposer 740. A second chip 721 (such as a cache chip) in the second chip structure 720 may be connected to the substrate 710 by through silicon vias of the first Si interposer 740, thereby being in electrical connection with the substrate 710 in a vertical direction and implementing a circuit amplification via the first Si interposer 740.

However, in the semiconductor package 700, a signal transmission between the second chip 721 and a first chip 731 (such as a logic chip) of the first chip structure 730 requires a lateral signal transfer via the first redistribution layer 719, and the like, which causes transmission paths for electric signals of the semiconductor package 700 to be relatively long, thereby affecting rates of respective electric signal transmissions. In addition, the second chip 721 and the first chip 731 are arranged side by side in a plane, which causes a package area of the semiconductor package 700 to be relatively large.

In addition, for implementing electrical connections between the first and second chips 731 and 721 and the outside, the semiconductor package 700 may further include a second redistribution layer 711 arranged at a lower portion of the substrate 710 and a second silicon (Si) interposer 713 connected between the first and second redistribution layers 719 and 711 in the substrate 710. The first and second chips 731 and 721 may be electrically connected to the second redistribution layer 711 in the vertical direction via the first redistribution layer 719 and through silicon vias 715a and 715b of the second Si interposer 713, and connected to an external substrate (e.g., an external printed circuit board (PCB)) via external connection terminals 735 disposed on the second redistribution layer 711.

That is, in the semiconductor package 700, the Si interposers are used to implement a high density of electrical path connections to match a requirement for a high-density connection of the logic chip and the cache chip. However, Since Si interposers are relatively high in cost, it may be caused that the semiconductor package is relatively high in manufacturing cost. In addition, since current Si interposers are relatively low in yield, it may be caused that reliability of the semiconductor package is deteriorated.

On the contrary, referring to FIGS. 1A and 5, the semiconductor package 10 according to the example embodiments of the present disclosure may be compatible with a requirement for a high-density pin connection of the logic and cache chips by forming redistribution layers (RDLs), which match a micro-bump structure, on opposite surfaces of the package substrate 100 formed by a nanometer-scale-free process, and implement circuit amplifications of the logic and cache chips by the package substrate 100 and the RDLs thereon. As such, even if Si interposers are not used, the connection requirement of the logic and cache chips may be satisfied. Therefore, a manufacturing cost of the semiconductor package may be reduced, and the yield and the reliability of the semiconductor package may be improved. In addition, as illustrated in FIGS. 1A and 5, the 3D semiconductor package 10 according to the example embodiments of the present disclosure may further form transmission paths for electric signals between/among the cache chip(s), the package substrate, the logic chip, and the external PCB in a substantially vertical direction, so that the transmission paths for electric signals in the 3D semiconductor package 10 may be effectively shortened, and the 3D semiconductor package 10 may become more compact.

While aspects of example embodiments have been particularly shown and described, it will be understood that various changes in form and details may be made therein without departing from the spirit and scope of the following claims.

What is claimed is:

1. A three-dimensional semiconductor package, comprising:
a package substrate having a first surface and a second surface opposite to the first surface;
a first redistribution layer on the first surface of the package substrate, the first redistribution layer having a first surface and a second surface opposite to each other, the second surface of the first redistribution layer facing the surface of the package substrate;
a first chip on the first surface of the first redistribution layer, electrically connected to the first redistribution layer, and comprising first through silicon vias;
first connection terminals electrically connected to one ends of the first through silicon vias, the other ends of the first through vias being closer to the first redistribution layer;
a second redistribution layer on the second surface of the package substrate, the second redistribution layer having a first surface and a second surface opposite to each other, the first surface of the second redistribution layer facing the second surface of the package substrate; and
a second chip on the second surface of the second redistribution layer and electrically connected to the second redistribution layer,
wherein the first redistribution layer and the second redistribution layer are interconnected through the package substrate, and
wherein the first chip and the second chip are disposed within a periphery of the package substrate when viewed in a plan view.

2. The three-dimensional semiconductor package of claim 1, wherein the first chip comprises a logic chip, and the second chip comprises a cache chip.

3. The three-dimensional semiconductor package of claim 1, wherein the package substrate is not a silicon substrate or a silicon interposer.

4. The three-dimensional semiconductor package of claim 1, further comprising first connection members between the first chip and the first redistribution layer and electrically connecting the first chip to the first redistribution layer, and second connection members between the second chip and the second redistribution layer and electrically connecting the second chip to the second redistribution layer,
wherein the first connection members and the second connection members comprise micro-bumps.

5. The three-dimensional semiconductor package of claim 4, further comprising a non-conductive film,
wherein the non-conductive film is disposed in a space between the first chip and the first redistribution layer and around the first connection members.

6. The three-dimensional semiconductor package of claim 1, wherein the first chip is provided in plural so that there are a plurality of first chips,
wherein the plurality of first chips are disposed side by side on the first surface of the first redistribution layer, and
wherein each of the plurality of first chips is electrically connected to the first redistribution layer.

7. The three-dimensional semiconductor package of claim 1, wherein the second chip is provided in plural so that there are a plurality of second chips, wherein:
the plurality of second chips are sequentially stacked on the second surface of the second redistribution layer and electrically connected to each other through second through silicon vias, and
a lowermost one of the plurality of second chips is electrically connected to the second redistribution layer.

8. The three-dimensional semiconductor package of claim 1, further comprising:
a plurality of second connection terminals disposed on the first surface of the first redistribution layer, surrounding the first chip, and connected to the first redistribution layer,
wherein each of the plurality of second connection terminals has a size greater than that of each of the first connection terminals.

9. The three-dimensional semiconductor package of claim 8, wherein the plurality of second connection terminals comprise at least one of a transmission terminal and a
a dummy terminal.

10. The three-dimensional semiconductor package of claim 1, further comprising a molding layer, at least a portion of the molding layer disposed on the second surface of the package substrate and on the second chip and the second redistribution layer.

11. The three-dimensional semiconductor package of claim 1, wherein the second chip is provided in plural so that there are a plurality of second chips, wherein:
the plurality of second chips disposed side by side on the second surface of the second redistribution layer, and
each of the plurality of second chips is electrically connected to the second redistribution layer.

12. A three-dimensional semiconductor package, comprising:
a package substrate having a first surface and a second surface opposite to the first surface;
a first redistribution layer on the first surface of the package substrate;
a first chip on the first redistribution layer and electrically connected to the first redistribution layer, and comprising first through silicon vias;
first connection terminals electrically connected to ends of the first through silicon vias;
a second redistribution layer on the second surface of the package substrate; and
a second chip on the second redistribution layer and electrically connected to the second redistribution layer,
wherein the first chip and the second chip are disposed within a periphery of the package substrate when viewed in a plan view.

13. The three-dimensional semiconductor package of claim 12, wherein the first chip comprises a logic chip and the second chip comprises a cache chip.

14. The three-dimensional semiconductor package of claim 12, further comprising first connection members between the first chip and the first redistribution layer and electrically connecting the first chip to the first redistribution layer; and
second connection members between the second chip and the second redistribution layer and electrically connecting the second chip to the second redistribution layer.

15. The three-dimensional semiconductor package of claim 14, wherein the first connection members comprise micro-bumps, and
wherein the second connection members comprise micro-bumps.

16. The three-dimensional semiconductor package of claim 14, further comprising a non-conductive film,
wherein the non-conductive film is disposed in a space between the first chip and the first redistribution layer and around the first connection members.

17. The three-dimensional semiconductor package of claim 12, wherein the first chip is provided in plural so that there are a plurality of first chips,
wherein the plurality of first chips are disposed side by side on the first redistribution layer, and
wherein each of the plurality of first chips is electrically connected to the first redistribution layer.

18. A three-dimensional semiconductor package, comprising:
a package substrate having a first surface and a second surface opposite to the first surface;
a first redistribution layer on the first surface of the package substrate;
a plurality of first chips on the first redistribution layer and electrically connected to the first redistribution layer, and comprising first through silicon vias;
first connection terminals electrically connected to ends of the first through silicon vias;
a second redistribution layer on the second surface of the package substrate;
a plurality of second chips on the second redistribution layer and electrically connected to the second redistribution layer;
first connection members between the plurality of first chips and the first redistribution layer and electrically connecting the plurality of first chips to the first redistribution layer; and
second connection members between the plurality of second chips and the second redistribution layer and electrically connecting the plurality of second chips to the second redistribution layer.

19. The three-dimensional semiconductor package of claim 18, wherein the plurality of first chips and the plurality of second chips are disposed within a periphery of the package substrate when viewed in a plan view.

20. The three-dimensional semiconductor package of claim 18, wherein the first chip comprises a logic chip, and the second chip comprises a cache chip.
